(19) United States
(12) Patent Application Publication
(10) Pub. No.: US 2011/0247685 A1
(43) Pub. Date: Oct. 13, 2011

(54) THIN-FILM SOLAR CELL AND METHOD FOR MANUFACTURING THE SAME

(75) Inventor: Kensuke Takenaka, Tsukuba-city (JP)

(73) Assignee: FUJI ELECTRIC HOLDINGS CO., LTD., Kawasaki-shi (JP)

(21) Appl. No.: 13/043,884

(22) Filed: Mar. 9, 2011

(30) Foreign Application Priority Data
Mar. 16, 2010 (JP) 2010-059204

(51) Int. Cl. H01L 31/0236; H01L 31/18; H01L 31/0232

(52) U.S. Cl. 136/256; 438/71; 257/E31.13

(57) ABSTRACT

A thin-film solar cell can include a light-reflective metal electrode layer, a first transparent conductive layer, a semiconductor layer and a front transparent conductive layer. The metal electrode layer can be formed on a substrate and has an uneven structure. The first transparent conductive layer can contain an amorphous transparent conductive material. The thin-film solar cell further can have a second transparent conductive layer between the first transparent conductive layer and the semiconductor layer. The second transparent conductive layer can be made of a crystalline transparent conductive material. Due to the first transparent conductive layer made amorphous, the surface roughness of the metal electrode layer is reduced so that the semiconductor layer can be formed with a good film quality.

### BACKGROUND OF THE INVENTION

1. Field of the Invention

Embodiments of the present invention relate to a thin-film solar cell and a method for manufacturing the same. Particularly, they relate to a thin-film solar cell using an electrode layer for diffusing and reflecting light, and a method for manufacturing the thin-film solar cell.

2. Description of the Background Art

In recent years, solar cells have been put into wide use as primary electric/electronic component devices for photovoltaic power generation. Of various kinds of solar cells, thin-film solar cells have particularly attracted attention. This is because thin-film solar cells are manufactured as devices requiring smaller resources and lower energy and causing less environmental loads than crystalline silicon solar cells using silicon wafers etc. Of such thin-film solar cells, some known cells use thin-film photoelectric conversion layers, that is, power generation layers with various crystallinities such as amorphous, microcrystal, polycrystal, etc. Those power generation layers for use in thin-film solar cells are characterized in that their amount of photoelectric conversion is chiefly limited by their film thickness. However, when the photoelectric conversion efficiency is intended to be enhanced by increase of the film thickness of a power generation layer, processing time in a manufacturing process increases. Thus, the amount of production decreases and the manufacturing cost increases. Therefore, there is a request for enhancement of the photoelectric conversion efficiency in a thin-film solar cell without increasing the film thickness of a power generation layer.

Under such a request, a conductive light-reflective film has been broadly used. In the conductive light-reflective film, a metal layer with a high light-reflectivity is used as an electrode located on the back surface (back side) of a power generation layer in view from the entrance side of light so that the film can serve as a light-reflective film as well as an electrode film. In the following description, the side where light is incident in view from a substrate or the power generation layer will be referred to as “front side”, and the opposite side will be referred to as “back side”. When the conductive light-reflective film is disposed as a back electrode on the back side in view from the power generation layer, light which has not contributed to power generation can be reflected toward the power generation layer again. Thus, the improvement of the photoelectric conversion efficiency can be expected.

In a solar cell having a conductive light-reflective film as a back electrode, an uneven structure may be formed in a front-side interface or boundary surface of the back electrode in order to further improve the conversion efficiency. This is to diffuse light reflected by the back electrode. When the back electrode diffuses and reflects light, there can be expected an effect that, of light which cannot be absorbed in a power generation layer but enters the back electrode, a component of reflected light which will exit the solar cell can be reduced. On this occasion, when most of the diffused and reflected light does not exit the solar cell but can be confined in the solar cell to contribute to photoelectric conversion again, the total amount of photoelectric conversion in the solar cell can be increased. The effect that the photoelectric conversion efficiency is thus enhanced by diffusion and reflection is referred to as light trapping effect.

Japanese Application Publication No. JP-A-4-334069 (hereinafter “JP-A-4-334069”) has disclosed an example of a method for using a light trapping effect in a thin-film solar cell. The method disclosed in JP-A-4-334069 is a method for producing an uneven structure in a conductive light-reflective film. Examples of materials for the conductive light-reflective film disclosed in JP-A-4-334069 include metals such as aluminum (Al) and silver (Ag), alloys of those metals, or alloys of those metals and silicon (Si). Japanese Application Publication No. JP-A-4-218977 (hereinafter “JP-A-4-218977”) has disclosed another example of a method for forming a conductive light-reflective film. JP-A-4-218977 has suggested a method for forming an uneven structure using a metal double-layer structure of a semi-continuous film and a continuous film. The semi-continuous film means a film which has a large nonuniformity in thickness and which is partially disconnected widthwise or lengthwise. On the other hand, the continuous film means a film where such a disconnected portion is absent. Further, Japanese Application Publication No. JP-A-9-162430 (hereinafter “JP-A-9-162430”) has disclosed another example of a method for forming a conductive light-reflective film with an uneven structure. The method suggested in JP-A-9-162430 is a method using a metal multilayered structure of an Ag film and an Al or Al-alloy film. Japanese Application Publication No. JP-A-8-288529 (hereinafter “JP-A-8-288529”) has also disclosed further another method. JP-A-8-288529 has suggested that a thin metal film with an appropriate uneven structure is used as a lower electrode. There is another relevant disclosure in Japanese Application Publication No. JP-A-2003-101052 (hereinafter “JP-A-2003-101052”). JP-A-2003-101052 has disclosed a conductive light-reflective film with an uneven structure provided with specific properties due to an optimized amount of an additive in a constituent material of the conductive light-reflective film, and a method for forming the conductive light-reflective film.

However, when hydrogenated microcrystalline silicon (μc-Si:H, hereinafter referred to as “μc-Si”) serving as a typical configuration of the thin-film solar cell is used for the power generation layer, the power generation layer should be formed on a surface of the uneven structure to deteriorate the properties of the power generation layer. That is, when a film which will serve as the μc-Si power generation layer is made to grow using the surface of the aforementioned uneven structure as an underlayer, a large number of μc-Si crystal grains with different crystal orientations are produced. As a result, with the growth of the power generation layer, macroscopic crystal grains with different orientations are produced, and the crystal grains collide with one another during the growth of the film. Due to such a mechanism, the number of defects increases in the μc-Si power generation layer. As described above, it has been known that the uneven structure provided in the surface where the power generation layer should be formed has an adverse effect on the film quality of the μc-Si power generation layer.

The situation is similar also in the case where hydrogenated amorphous silicon (a-Si:H, hereinafter referred to as “a-Si”) or hydrogenated amorphous silicon germanium (“a-SiGe”) is used for the power generation layer. That is, since these kinds of power generation layers are not crystallized, the influence of the uneven structure is more relaxed than that of μc-Si, and there is a tendency to have a larger-size uneven structure. However, when an excessively large uneven structure is present even in a thin-film solar cell using such a power generation layer, the underlying structure on which a power generation layer should grow has a large effect on the whole of the a-Si or a-SiGe power generation layer.

As described above, in any case where μc-Si, a-Si or a-SiGe is used for a power generation layer, the film quality of the power generation layer is affected by the surface of an uneven structure on which the power generation layer is formed. As a result, the properties of the thin-film solar cell deteriorate as a whole.

Here, solar cells are often roughly classified into a superstrate type and a substrate type. In this classification, attention is paid to the positional relationship between a substrate and a photoelectric conversion layer. Specifically, attention is paid to which configuration is provided for light incident on a power generation layer, that is, a photoelectric conversion layer for power generation, a configuration (superstrate type) where the light transmitted through a substrate is incident on the photoelectric conversion layer or a configuration (substrate type) where the light transmitted through the photoelectric conversion layer is incident on the substrate. As described previously, in a superstrate type solar cell, light for power generation is transmitted through a substrate and then incident on a power generation layer. To this end, in the superstrate type solar cell, a transparent or translucent substrate is used and disposed on the front side of the formed power generation layer. On the other hand, in a substrate type solar cell, light for power generation is incident on a power generation layer without being transmitted through a substrate. Thus, an opaque or poorly translucent substrate can be used in the substrate type solar cell. The substrate is disposed on the back side with respect to the formed power generation layer.

Japanese Application Publication No. JP-A-2000-252499 (hereinafter “JP-A-2000-252499”) has suggested a method which uses an uneven electrode in a superstrate type solar cell and which can prevent the film quality from deteriorating. According to this method, a transparent electrode with irregularities is used as an underlayer on which crystals of crystalline silicon should grow, and the surface of the transparent electrode is etched. JP-A-2000-252499 is intended to smooth the uneven shape of the surface of the transparent electrode before the start of growth of crystalline Si so as to prevent the film quality of crystals from deteriorating.

It is difficult to make use of the light trapping effect while obtaining a good film quality in a substrate type thin-film solar cell. When an uneven structure is formed in the surface of a back electrode in order to obtain the light trapping effect in the substrate type thin-film solar cell, a power generation layer is inevitably formed on the uneven structure of a conductive light-reflective film formed as the back electrode and serving as an underlayer of the power generation layer. That is, in the substrate type thin-film solar cell, the technical request to form the uneven structure for the light trapping effect is hardly compatible with the technical request to provide a good film quality to attain the improvement of efficiency.

More particularly, assume that the shape of an uneven structure of a metal electrode on a substrate is made gentle or smooth enough to improve the film quality of a power generation layer. When the metal electrode is formed on such conditions, a satisfactory light trapping effect cannot be obtained. The light which cannot be absorbed by the power generation layer but has reached the metal electrode is reflected by the metal electrode. However, diffusion of the light at that time deteriorates.

On the contrary, a back electrode desirable to obtain a satisfactory light trapping effect is a metal electrode with satisfactory diffusion, that is, with a sharp or rough uneven structure. A metal electrode with such a rough uneven structure is typically characterized by large surface roughness (Ra). However, when conditions desirable for the light trapping effect are applied directly to the uneven structure of the metal electrode for manufacturing a back electrode for use in a μc-Si solar cell, it is not possible to manufacture a solar cell with good properties. The back electrode with the sharp or rough uneven structure, that is, large surface roughness increases the light trapping effect which should be achieved by the back electrode, but deteriorates the μc-Si film quality of the power generation layer at the same time. The improvement in the amount of photoelectric conversion obtained by the large surface roughness of the metal electrode is canceled by the influence of the photoelectric conversion efficiency lowered due to the large surface roughness.

A method for attaining both the diffusion for obtaining a satisfactory light trapping effect and the good crystal quality of a μc-Si power generation layer in a substrate type solar cell is unknown yet. As a result, in order to enhance the photoelectric conversion efficiency of a μc-Si power generation layer of a substrate type solar cell, it is inevitable in the present circumstances to increase the thickness of a substantially intrinsic μc-Si layer. Not to say, the increase of the film thickness of the μc-Si layer leads to increase of processing time for the process of manufacturing a photoelectric conversion layer. It is thus not easy to produce a substantially intrinsic μc-Si power generation layer as a thin film. Circumstances are the same as mentioned above in the case where an amorphous material is used for a power generation layer.

In the superstrate type solar cell disclosed in JP-A-2000-252499, the transparent electrode whose uneven shape is controlled by etching is located on the front side with respect to the power generation layer. On this occasion, the substrate is disposed on the front side with respect to the power generation layer while the back electrode is formed on the back side after the power generation layer is formed. That is, the uneven structure of the back electrode disclosed in JP-A-2000-252499 is not formed yet at the point of time when the power generation layer is formed.

### SUMMARY OF EMBODIMENTS OF THE INVENTION

In order to solve the aforementioned problems, the present inventor of the application paid attention to a transparent conductive layer provided between a metal electrode layer and a power generation layer in the case where a back electrode formed on the substrate serves as the metal electrode layer. The inventor of the application found that at least some of the problems can be solved by making crystallinity of the transparent conductive layer amorphous, that is, by containing an amorphous transparent conductive material in at least part of the transparent conductive layer.

That is, for example, assume that the transparent conductive layer is made of a crystalline transparent conductive material. When the transparent conductive layer is disposed on the metal electrode layer in this case, additional irregularities may be given to the uneven structure of the metal electrode layer due to crystals of the transparent conductive layer. On the other hand, when the transparent conductive layer disposed on the metal electrode layer contains an amorphous transparent conductive material, the uneven structure of the metal electrode layer can be made flat and smooth due to the transparent conductive layer. When this characteristic is used aggressively, at least some of the problems can be solved.

That is, according to an aspect of the invention, there is provided a thin-film solar cell including: a metal electrode layer which has a first surface and a second surface, the first surface including an uneven structure with light reflectivity, the metal electrode layer being disposed on one surface of a substrate so as to allow the second surface to face the one surface of the substrate; a first transparent conductive layer which contains an amorphous transparent conductive material; a semiconductor layer; and a front transparent conductive layer; wherein the first transparent conductive layer, the semiconductor layer and the front transparent conductive layer are disposed on the first surface of the metal electrode layer sequentially from the substrate.

Further, according to another aspect of the invention, there is provided a method for manufacturing a thin-film solar cell. That is, there is provided the method for manufacturing a thin-film solar cell including the steps of: placing a metal electrode layer on one surface of a substrate, the metal electrode layer including a first surface and a second surface, an uneven structure with light reflectivity being provided on the first surface, the second surface facing the one surface of the substrate; placing a first transparent conductive layer containing an amorphous transparent conductive material; placing a semiconductor layer; and placing a front transparent conductive layer; wherein the step of placing the first transparent conductive layer, the step of placing the semiconductor layer and the step of placing the front transparent conductive layer are executed sequentially in this order after the step of placing the metal electrode layer.

In each aspect of the invention, it is possible to attain a configuration by which satisfactory diffusion in reflection of a metal electrode layer can be obtained, that is, a configuration in which a surface or an interface serving as an underlayer of a power generation layer hardly gives an adverse effect to the film quality of the power generation layer even when the surface roughness of the metal electrode layer is increased to obtain a satisfactory light trapping effect, so that it is possible to provide a technique for improving the photoelectric conversion efficiency of a solar cell.

More specifically, in each of the aforementioned aspects of the invention, a metal electrode layer is formed on one surface of a substrate of glass, resin or the like. The metal electrode layer has a first surface and a second surface. An uneven structure is formed in the first surface, and the second surface faces the substrate. The metal electrode layer thus configured serves as a conductive light-reflective film by itself, and also serves to diffuse and reflect reflected light due to the uneven structure in the first surface. The substrate in each aspect of the invention is defined in conjunction with the metal electrode layer. That is, the aforementioned substrate may contain any base or substance with any structure or shape disposed on the second surface side of the metal electrode layer. Examples of substrates according to each aspect of the invention may include a substrate made from a single material, a substrate containing some materials, a substrate subjected to some processing, a substrate having a multilayer configuration, and a substrate having irregularities in itself. In other words, the second surface of the metal electrode layer, that is, the interface between the metal electrode layer and the substrate may have any shape. According to an example of the shape, the metal electrode layer may be configured to include a first surface with an uneven structure and a smooth second surface. According to another example, the metal electrode layer may be configured so that the second surface has irregularities, for example, in accordance with irregularities of the substrate, and the uneven structure of the first surface reflects the irregularities of the second surface.

In the aforementioned thin-film solar cell, a first transparent conductive layer is provided to put the metal electrode layer between the first transparent conductive layer and the substrate. The first transparent conductive layer contains an amorphous transparent conductive material. Due to the first transparent conductive layer containing the amorphous transparent conductive material, the uneven structure in the first surface of the metal electrode layer is flattened or smoothed by the first transparent conductive layer so that the surface roughness can be reduced. Here, the surface roughness can be measured by various indices. Typically, an arithmetical mean deviation Ra in a contour curve expressing the surface shape of a subject to be measured may be measured. Unless otherwise stated, the arithmetical mean deviation will be used hereinafter as “surface roughness” or Ra. However, any aspect in which the surface roughness is defined using any other measurement index is also included as a part of aspects of the invention. In addition, roughness in a surface which cannot be always regarded as “surface”, for example, roughness in an interface will be also defined herein by use of the word “surface roughness”. The “surface roughness” in such a case means “surface roughness” at the point of time when the interface to be measured appears as a surface in process of manufacturing. In this manner, as long as roughness of the surface can be measured at least in some stage in process of manufacturing, the roughness of the surface can be described even if the surface cannot be regarded as a surface after another film is formed on the surface.

Then, a semiconductor layer is placed to put the first transparent conductive layer between the semiconductor layer and the metal electrode layer. The semiconductor layer is not specified specially, but it may be formed, for example, as a power generation layer using microcrystal silicon or a power generation layer using a-Si. A power generation layer with a multilayer structure having a uni-junction of any crystallinity built into layers which, for example, include an n-type semiconductor layer, an i-type semiconductor layer and a p-type semiconductor layer may be used. Further, the power generation layer may be designed as a multi-junction or tandem type configuration with two or more junctions, in which, for example, a first n-i-p junction of an n-type μc-Si layer, an i-type μc-Si layer and a p-type μc-Si layer and a second n-i-p junction of an n-type a-Si layer, an i-type a-Si layer and a p-type a-Si layer are laminated through a tunnel junction layer. In addition, another semiconductor than silicon, such as amorphous SiGe, may be used according to another aspect of the invention. In addition, a silicon alloy such as a-SiO (amorphous silicon oxide) or a μc-SiO (microcrystal silicon oxide) may be used for an n-layer, a p-layer or an interface layer between layers. Further, a material different from the material of an i-type semiconductor layer may be used for an n-type semiconductor layer or a p-type semiconductor layer.

Further, a front transparent conductive layer is provided to put the semiconductor layer between the front transparent conductive layer and the first transparent conductive layer. The front transparent conductive layer is disposed on the side (front side) of the semiconductor layer where light for generating electric power should be incident, so that the front transparent conductive layer together with the metal electrode layer serves as an electrode of the thin-film solar cell.

In the thin-film solar cell configured thus, a collector electrode layer is formed in accordance with necessity so that the solar cell can be operated. With the configuration described above, each aspect of the invention contributes to production of an excellent-performance solar cell with a further reduced environmental load. This contribution is, for example, attained by a thin-film solar cell using μc-Si or a-Si for a power generation layer, which can be manufactured with a reduced thickness of a substantially intrinsic silicon layer while preventing the photoelectric conversion efficiency from lowering.

Here, the expression “sequentially” used herein for defining the placement of some layers will be described. The expression is written, for example, in such a form that a first layer, a second layer and a third layer are disposed “sequentially in this order”. That description means that the first layer, the second layer and the third layer are disposed so that the first layer and the second layer are put on top of each other directly or with another layer therebetween, and further the second layer and the third layer are put on top of each other directly or with another layer therebetween. That is, it is intended by this description that the first layer, the second layer and the third layer are disposed keeping this order while allowing other unspecified layers to be placed between the first layer and the second layer and between the second layer and the third layer. The description about the placement can be also applied to the description about steps that the first step, the second step and the third step are executed “sequentially in this order”. That is, this description means that the second step is executed after the first step is executed, and the third step is executed after the second step is executed. This description allows other unspecified steps to be executed between the first step and the second step and between the second step and the third step. Further, this description also allows other unspecified steps to be executed simultaneously with or in parallel with any specified step.

In each aspect of the invention as described above, a second transparent conductive layer containing a crystalline transparent conductive material may be further provided and disposed between the first transparent conductive layer and the semiconductor layer as another preferred aspect of the invention. Such a layout is embodied by another aspect of a method for manufacturing a solar cell, which further includes the step of placing a second transparent conductive layer containing a crystalline transparent conductive material, the step being executed between the step of placing the first transparent conductive layer and the step of placing the semiconductor layer.

Of those layers, for example, the first transparent conductive layer and the second transparent conductive layer are laminated directly on each other and have almost the same material composition according to another preferred aspect of the invention. It is because the first transparent conductive layer which is amorphous and the second transparent conductive layer which is crystalline can be laminated and formed on each other easily only by changing their film-formation conditions, for example, by a sputtering method using a target of one and the same material for forming these transparent conductive layers.

According to any aspect of the invention, a satisfactory light trapping effect and an effect of preventing the film quality of a formed semiconductor layer from deteriorating can be made compatible in a substrate type thin-film solar cell.

### BRIEF DESCRIPTION OF THE DRAWINGS

FIG. 1 is a schematic sectional view showing the configuration of a solar cell in a first embodiment of the invention;

FIG. 2 is a schematic sectional view showing the configuration of another solar cell in the first embodiment of the invention;

FIG. 3 is a schematic sectional view showing the configuration of a further solar cell in the first embodiment of the invention; and

FIG. 4 is a flow chart schematically showing a method for manufacturing a solar cell in a second embodiment of the invention.

### DETAILED DESCRIPTION OF THE INVENTION

Embodiments of the invention will be described below. Unless otherwise stated in the following description, parts or elements common to the drawings are given by the same numerals correspondingly. In addition, the drawings do not always show the elements in the embodiments with a proper scale relative to one another.

### First Embodiment

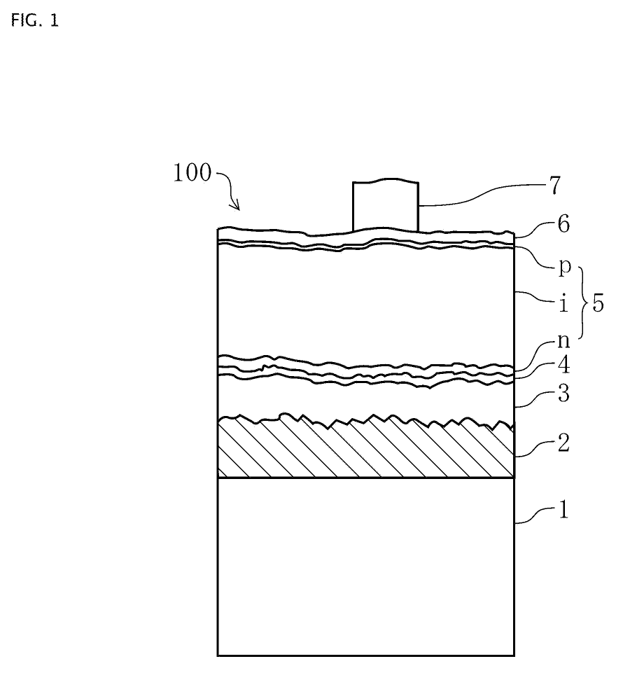

FIG. 1 is a schematic sectional view of a solar cell 100 according to a first embodiment of the invention. The solar cell 100 is a thin-film solar cell with a uni-junction structure using a conductive light-reflective film and using μc-Si for a photoelectric conversion layer.

In the solar cell 100, a metal electrode layer 2 is formed on one surface of a substrate 1, which surface looks upward in the paper of FIG. 1. Here, various known substrates such as an insulating substrate, a flexible substrate and a plastic film substrate may be used as the substrate 1. In addition, the metal electrode layer 2 has a thickness defined by a surface (second surface) facing the substrate 1 and a surface (first surface) looking upward in FIG. 1. Here, the first surface is formed out of metal so as to have light-reflectivity and have an uneven structure. The uneven structure serves to diffuse and reflect light incident thereon. Surface roughness Ra of the uneven structure is measured and shows a certain value.

Further, a first transparent conductive layer 3 is provided in the solar cell 100. The first transparent conductive layer 3 contains an amorphous transparent conductive material. The first transparent conductive layer 3 is placed in a position where the metal electrode layer 2 is put between the first transparent conductive layer 3 and the substrate 1, that is, in a position above the metal electrode layer 2 in FIG. 1. In the solar cell 100 depicted in FIG. 1, the first transparent conductive layer 3 is placed directly on the uneven structure in the first surface of the metal electrode layer 2. Thus, the surface of the transparent conductive layer 3 looking upward in FIG. 1 is made flatter or smoother than the surface (first surface) of the metal electrode layer 2 looking upward. That is, when the value of the surface roughness of the surface of the first transparent conductive layer 3 is measured in the stage where the first transparent conductive layer 3 has been formed, the value of the surface roughness is smaller than that of the surface roughness of the first surface of the metal electrode layer 2. Thus, the first transparent conductive layer 3 containing an amorphous transparent conductive material serves not only to take charge of electric conduction and transmit light but also to exert an effect to flatten or smooth the uneven structure.

A semiconductor layer 5 is further formed in the solar cell 100. The semiconductor layer 5 is placed in a position where the first transparent conductive layer 3 is put between the semiconductor layer 5 and the metal electrode layer 2, that is, above the first transparent conductive layer 3 in FIG. 1. The semiconductor layer 5 may have a desired configuration for operating the solar cell 100 as a thin-film solar cell. The semiconductor layer 5 serving as a power generation layer in the solar cell 100 according to this embodiment has a photoelectric conversion layer of an n-i-p uni-junction structure with μc-Si, in which an n-type μc-Si layer, an i-type μc-Si layer and a p-type μc-Si layer are laminated sequentially from the substrate 1.

Then, a front transparent conductive layer 6 is placed in a position where the semiconductor layer 5 is put between the front transparent conductive layer 6 and the first transparent conductive layer 3. For example, ITO may be used for the front transparent conductive layer 6 used in the solar cell 100. Examples of other materials that can be used for the front transparent conductive layer 6 include transparent conductive oxides such as IZO, TiO₂, ZnO, SnO₂, In₂O₃, Ga₂O₃, IGO, IGZO, etc.

A collector electrode layer 7 is placed above the front transparent conductive layer 6. Metal such as Ag, Al, Ni, Ti, etc. or an alloy containing one selected from those metals may be used as the material of the collector electrode layer 7. The collector electrode layer 7 may have a layer structure of either a single-layer film or a multilayer film.

The solar cell 100 including the metal electrode layer 2 and the collector electrode layer 7 as output electrodes is configured as described above.

The solar cell 100 according to this embodiment has a second transparent conductive layer 4 as a part of the configuration of the solar cell 100 as shown in FIG. 1. This is not only to operate the solar cell 100 simply as a solar cell but also to more enhance the reliability of the operation of the solar cell 100. That is, in a solar cell designed not to have the second transparent conductive layer 4, indium having a low melting point may be thermally diffused into the semiconductor layer 5, specifically the n-type μc-Si layer or the i-type μc-Si layer during the process for forming the semiconductor layer 5, specifically during the process for forming the n-type μc-Si layer or the process for forming the i-type μc-Si layer. Such diffusion leads to deterioration of the film quality of the semiconductor layer to thereby deteriorate the properties as a solar cell. On the other hand, in the solar cell 100, as will be described later, the aforementioned second transparent conductive layer 4 is placed between the first transparent conductive layer 3 and the semiconductor layer 5 so that the diffusion can be reduced or suppressed. Thus, the properties of the solar cell 100 can be prevented from deteriorating, so that the reliability of the operation of the solar cell 100 can be enhanced.

In the solar cell 100, as described above, the uneven structure in the first surface of the metal electrode layer 2 is flattened or smoothed. The flattening or smoothing is achieved by the first transparent conductive layer 3 using an amorphous transparent conductive material. With this configuration, the uneven structure in the first surface of the metal electrode layer 2 can be formed into a preferred shape in view from light trapping effect. At the same time, the shape of the semiconductor layer 5 side surface of the first transparent conductive layer 3 or the second transparent conductive layer 4 serving as an underlayer of the semiconductor layer 5 can be formed into a preferred shape in view from the formation of the semiconductor layer 5.

Next, description will be made on amorphous transparent conductive materials which can be selected as a preferable transparent conductive material of the first transparent conductive layer in this embodiment to this end. In the solar cell 100 according to this embodiment, a material containing an amorphous transparent conductive material is used for the first transparent conductive layer 3 to flatten or smooth the uneven structure as described above. Any amorphous transparent conductive material may be used as the material of the first transparent conductive layer 3 as long as it can attain such an end. To take the first transparent conductive layer 3 as an example, it is preferable that the first transparent conductive layer 3 contains a transparent conductive material selected from a group consisting of In₂O₃—ZnO, In₂O₃—Ga₂O₃—ZnO and In₂O₃—Ga₂O₃. Such a transparent conductive material shows a good electric characteristic and a good transparency in the state where it is formed as an amorphous transparent conductive film even when the substrate has a high temperature.

In addition to such a material used for the first transparent conductive layer, a transparent conductive material free from indium may be used for the second transparent conductive layer 4 according to a further preferred embodiment. As a result, even if the substrate reaches a high temperature when, for example, the semiconductor layer 5 is formed, indium derived from the first transparent conductive layer 3 can be prevented from being diffused into the semiconductor layer 5. As the transparent conductive material free from indium, a transparent conductive material based on a metal oxide film free from indium is typically used. For example, the material is a transparent conductive material selected from ZnO, SnO₂, Ga₂O₃, ZnO (zinc oxide), SnO₂ (tin oxide), GaO₂ (gallium oxide) and TiO₂ (titanium oxide), or a mixture of those metal oxides. Of those, ZnO is used the most typically. Diffusion of indium described here can be prevented if the second transparent conductive layer made of a material free from indium is formed, for example, into an appropriate thickness.

A configuration in which only one layer of an amorphous transparent conductive film free from indium is used in order to enhance practicability is also included in this embodiment. In that case, an amorphous material free from any low-melting material such as indium is used for the first transparent conductive film 3. With such a configuration, the number of transparent conductive layers can be reduced. Thus, it is not necessary to provide a layer for preventing the aforementioned diffusion of indium, but flattening or smoothing can be achieved due to the amorphous transparent conductive layer.

In the configuration using the second transparent conductive layer 4 in the solar cell 100 according to this embodiment, the second transparent conductive layer 4 is made thinner than the first transparent conductive layer 3 as a further preferable configuration. Here, both the first transparent conductive layer 3 and the second transparent conductive layer 4 are inevitably affected by the nonuniformity of the metal electrode layer 2. Accordingly, the opposite surfaces of each layer of the first transparent conductive layer 3 and the second transparent conductive layer 4 are not always flat. Even in such a case, the thickness of each layer can be measured. For example, in order to obtain the thickness of the first transparent conductive layer 3, first, an average position of a profile drawn by a section of the first surface (surface where the uneven structure is formed) of the metal electrode layer 2 is obtained. Likewise, an average position of a profile drawn by a section of the semiconductor layer 5 side surface of the first transparent conductive layer 3 is obtained. A difference between those average positions is calculated. The calculated difference can be regarded as the thickness of the first transparent conductive layer 3. The thickness of the second transparent conductive layer 4 can be also measured in the same manner.

Such a method for measuring thickness based on profile is not limited specially. As an example of the method, a measuring method using an ultrathin section of the solar cell 100 may be used. In that method, the solar cell 100 is sliced perpendicularly to the substrate 1 by use of a microtome or the like to obtain an ultrathin section as a sample to be measured. When the sample section is observed by a transmission electron microscope (FE-TEM) or the like, film thickness can be measured. On that occasion, in order to specify an interface portion between the first transparent conductive film 3 and the second transparent conductive film 4, for example, it is effective to find out constituent elements and distributions thereof in each place of a sectional TEM image based on characteristic X-ray peaks of EDS spectra obtained by energy dispersive X-ray spectroscopy (TEM-EDS). Alternatively, a method using a scanning electron microscope (FE-SEM) etc. including a focused ion beam (FIB) device may be used as another example of the method for determining a profile to measure thickness. In the case of this method, a to-be-measured sample of the solar cell 100 is produced by micro-fabrication with which a section perpendicular to the substrate 1 is figured. When a sectional SEM image of the to-be-measured sample is photographed, characteristic X-ray peaks of EDS spectra obtained by energy dispersive X-ray spectroscopy (SEM-EDS) are obtained concurrently. Thus, constituent elements and distributions thereof in each place of the section can be determined. In this manner, the interface portion between the first transparent conductive film 3 and the second transparent conductive film 4 can be specified.

When the interface profile between layers in a section perpendicular to the substrate 1 in the solar cell 100 is determined by some kind of method, average thickness of each layer as described above can be calculated so that the thickness of the layer can be obtained. Thus, the thicknesses of the first transparent conductive layer 3 and the second transparent conductive layer 4 can be measured even when each layer is affected by nonuniformity in an actual solar cell.

Here, description will be made on the significance of defining the aforementioned relationship among thicknesses. Generally in an uneven structure produced due to the formation of a crystalline film, the degree of the uneven structure, that is, the surface roughness thereof has a tendency to increase in accordance with increase of the thickness of the film per se. Conversely, when the second transparent conductive layer 4 is made thinner than the first transparent conductive layer 3 as described above, the scope of materials which can be selected as the transparent conductive material of the second transparent conductive layer 4 can be widened. On this occasion, for example, the scope of materials which can be selected for the second transparent conductive layer 4 includes crystalline materials which may produce an uneven structure in itself. Even if such a material is used for the second transparent conductive layer 4, enough flatness allowed to form the semiconductor layer 5 can be secured when the thickness of the second transparent conductive layer 4 is relatively small. It is noted that a satisfactorily flattened or smoothed shape can be obtained in the total shape of the first transparent conductive layer 3 and the second transparent conductive layer 4.

Next, surface roughness in the solar cell 100 according to this embodiment will be described. The solar cell 100 is preferably configured so that the roughness (surface roughness) of the interface between the semiconductor layer 5 and a film or a layer which will be located on the substrate 1 side in view from the semiconductor layer 5 is made smaller than the surface roughness of the first surface (surface having an uneven structure) of the metal electrode layer 2. With the configuration where the surface roughness is defined thus, the surface roughness of the surface (first surface) which defines the light reflection of the metal electrode layer can be kept large enough to obtain a satisfactory light trapping effect, while the surface which serves as an underlayer to deposit or grow the semiconductor layer 5 thereon can be prevented from having adverse effects on the growth of the semiconductor layer. The aforementioned description is established regardless of whether the second transparent conductive layer 4 is placed or not. In addition, the surface roughness of the interface herein corresponds to the surface roughness of the surface which is just before the semiconductor layer 5 is deposited or grown.

More specifically, in the solar cell 100 according to this embodiment, adverse effects of the uneven structure on the growth of the semiconductor layer can be suppressed well particularly when the surface roughness Ra of the interface is, for example, made not higher than 15 nm. Further, according to the embodiment of the invention, the light trapping effect in the solar cell 100 can be exerted effectively when the surface roughness Ra of the first surface (upper surface in FIG. 1) of the metal electrode layer 2 is made not lower than 30 nm.

### Modification 1 of First Embodiment

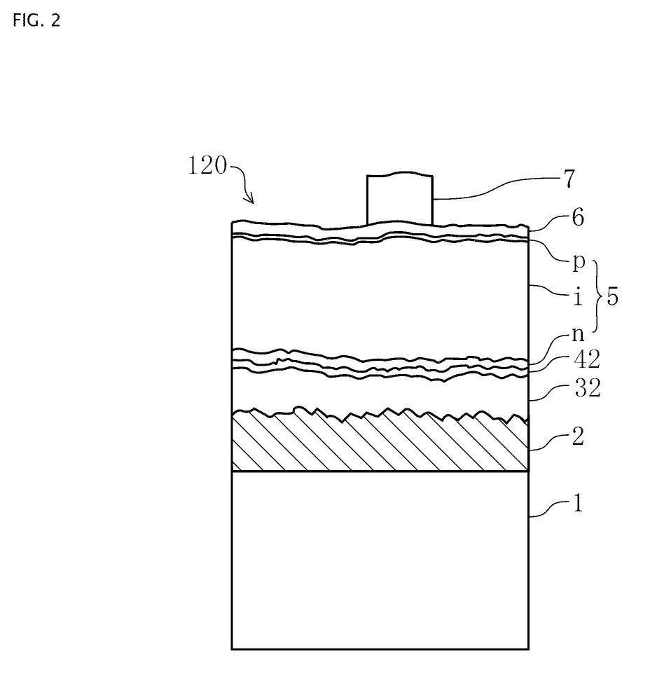

In addition to the aforementioned embodiment, the specific configuration of the solar cell according to the embodiment may be modified variously. FIG. 2 is a schematic sectional view showing the configuration of a solar cell 120 which will be described as Modification 1 of the embodiment. The solar cell 120 is configured in the same manner as the aforementioned solar cell 100 (FIG. 1), except the first transparent conductive layer 3 and the second transparent conductive layer 4.

In the solar cell 120, a first transparent conductive layer 32 and a second transparent conductive layer 42 are used. For example, the preferred material of the first transparent conductive layer 32 may contain a transparent conductive material selected from a group consisting of ZnO, SnO₂, GaO₂, TiO₂, ITO and In₂O₃. ZnO (zinc oxide), SnO₂ (tin oxide), GaO₂ (gallium oxide), TiO₂ (titanium oxide), ITO (indium oxide doped with tin) and In₂O₃ (indium oxide) listed here are transparent conductive materials based on metal oxides, which can be formed to have amorphous crystallinities. To this end, it is useful to appropriately select film-formation conditions such as substrate temperature during film formation. Also in this solar cell 120, the second transparent conductive layer 42 may be placed between the first transparent conductive layer 32 and the semiconductor layer 5. A crystalline transparent conductive material free from any low-melting material such as indium is preferably used for the second transparent conductive layer 42. As such a transparent conductive material, a transparent conductive material based on a metal oxide film may be used. For example, ZnO may be used.

The first transparent conductive layer 32 used in the solar cell 120 may not always show a good electric characteristic, that is, a satisfactory conductivity in some film-formation conditions. One of the factors suppressing the enhancement of the conductivity is that the first transparent conductive layer 32 must be made amorphous. For example, when the condition of a low substrate temperature during film formation is used as the film-formation condition for making the first transparent conductive layer 32 amorphous, the conductivity of the first transparent conductive layer 32 generally drops down as compared with the case where it is crystalline.

Here, even if the conductivity of the first transparent conductive layer 32 drops down, there can rarely arise a problem to obtain properties required as a solar cell. It is because the electric conductivity required of the first transparent conductive layer 32 is chiefly a film-thickness-direction electric conductivity. The film-thickness-direction electric conductivity is merely a very short distance electric conductivity in view from in-plane electric conductivity. Thus, the film-thickness-direction electric conductivity can rarely become a problem. However, it is also true that it is desirable to make the conductivity of the first transparent conductive layer as high as possible in order to further enhance the properties as a solar cell. The solar cell 120 therefore has a configuration in which the electric characteristic of the first transparent conductive layer 32 is complemented with the second transparent conductive layer 42. That is, the operation with which electrons or positive holes as carriers taking charge of electric conductivity are injected into a film disposed in contact with or closely to the second transparent conductive layer 42 can be achieved by the second transparent conductive layer 42. In that case, the second transparent conductive layer 42 contains a material or a component which can inject carriers into the first transparent conductive layer 32 or the semiconductor layer 5. Which to inject, electrons or positive holes, is determined depending on what conductive type to use for the first transparent conductive layer 32. Likewise, which film to be an injection target, the first transparent conductive layer 32 or the semiconductor layer 5, is determined depending on what films to form as these layers.

For example, in order to implement the configuration in which electrons are injected into the first transparent conductive layer 32 by the second transparent conductive layer 42, oxygen defects are controlled by the film-formation conditions in the formation steps of the first transparent conductive layer 32 and the second transparent conductive layer 42. Typically, the oxygen gas flow ratio in sputtering gas is controlled as the film-formation conditions. More specifically, first, conditions to reduce absorption loss are used for forming the first transparent conductive layer 32. These conditions are for preventing the transmittance from being reduced even if the first transparent conductive layer 32 is formed to be thick enough to flatten nonuniformity. To this end, the oxygen gas flow ratio, i.e. the ratio of oxygen gas to be mixed into sputtering gas is made higher than that in the conditions (conditions for forming the second transparent conductive layer 42) with which the resistivity is minimized. Thus, oxygen defects are reduced in the first transparent conductive layer 32 to lower the carrier electron density. As a result, the transmittance is improved. On that occasion, the mobility of the carrier electrons increases due to crystal defects which are also reduced concurrently. However, the lowered density of the carrier electrons has a greater influence. Thus, the electric resistance of the first transparent conductive layer 32 inevitably increases. On the other hand, as the conditions for forming the second transparent conductive layer 42, the oxygen flow ratio is adjusted to minimize the resistivity by priority. Moreover, the second transparent conductive layer 42 is formed to be thin enough to reduce the transmittance. There arises no special technical problem when the oxygen gas flow ratio is adjusted to form the first transparent conductive layer 32 and the second transparent conductive layer 42. That is, the oxygen gas flow ratio depends on conditions such as a target material, the kind of power source (for example, difference between DC and high-frequency current), discharge power, a distance between the target and the substrate, and pressure. Accordingly, under those conditions kept constant, the oxygen gas flow ratio to minimize the resistivity is obtained for the second transparent conductive layer 42. The conditions are determined for the first transparent conductive layer 32 to increase the oxygen gas flow ratio. Thus, for example, the oxygen gas flow ratio is set at an optimum value to minimize the resistivity when the second transparent conductive layer 42 is to be formed. When the first transparent conductive layer 32 is to be formed, the oxygen gas flow ratio is set to be higher in view of the transmittance. Thus, the second transparent conductive layer 42 can be operated to inject electrons as carriers into another layer.

According to a typical example in which a transparent conductive material for injecting carriers is used for the second transparent conductive layer 42 in order to obtain a high effect, a transparent conductive material selected from a group consisting of ZnO, SnO₂, GaO₂, TiO₂, ITO and In₂O₃ is used for the first transparent conductive layer 32. In addition, a material which can inject carriers into the first transparent conductive layer or the semiconductor layer is preferably used as the transparent conductive material of the second transparent conductive layer 42. More specifically, it is preferable that the second transparent conductive layer 42 is formed in the aforementioned conditions with which a sufficient amount of n-type or p-type conductive carriers can be produced.

Also in the solar cell 120, a transparent conductive material free from any low-melting material such as indium is preferably used as the material of the second transparent conductive layer 42. This situation is the same as the second transparent conductive layer 4 in the solar cell 100. That is, when the second transparent conductive layer 42 is free from indium and the first transparent conductive layer 32 contains indium, a situation that the indium is diffused into the semiconductor layer 5 can be prevented. Further, in the same manner as the solar cell 100 described as a preferred embodiment, it is also preferable in the solar cell 120 that the second transparent conductive layer 42 is made thinner than the first transparent conductive layer 32. In addition, in a preferred configuration of the solar cell 120, the surface roughness of the interface between the semiconductor layer 5 and the film or the layer contacting the semiconductor layer 5 on the substrate 1 side is made lower than the surface roughness of the first surface (surface with an uneven structure) of the metal electrode layer 2.

Further, when the surface roughness Ra of the interface in the solar cell 120 is made, for example, not higher than 15 nm, the influence on the growth of the semiconductor layer can be suppressed. Further, according to this embodiment, the light trapping effect in the solar cell 120 can be exerted effectively. This is attained by making the surface roughness Ra of the first surface (upper surface in FIG. 2) of the metal electrode layer 2 not lower than 30 nm.

### Modification 2 of First Embodiment

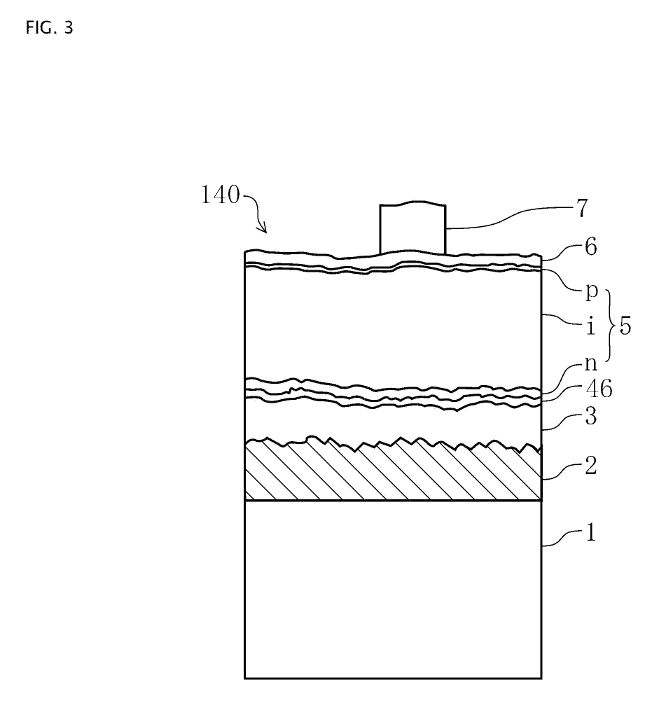

Next, Modification 2 of the first embodiment will be described with reference to FIG. 3. FIG. 3 is a schematic sectional view showing the configuration of a solar cell 140 which will be described as Modification 2 of the embodiment. The solar cell 140 has the same configuration as the aforementioned solar cell 100 (FIG. 1), except a third transparent conductive layer 46.

In the solar cell 140, the third transparent conductive layer 46 is placed in the same position as the second transparent conductive layer 3 of the solar cell 100. For the third transparent conductive layer 46, an amorphous transparent conductive material is used differently from a crystalline one for the second transparent conductive layer 4 (solar cell 100) or the second transparent conductive layer 42 (solar cell 120). In this case, the effect to flatten or smooth the uneven structure in the first surface of the metal electrode layer 2 becomes more conspicuous. This is because both the first transparent conductive layer 3 and the third transparent conductive layer 46 are amorphous. Further, it is possible to prevent the deterioration of reliability which may appear when an amorphous transparent conductive material containing indium is used for the first transparent conductive layer 3. The effect is attained when, for example, an amorphous transparent conductive material free from indium is used for the third transparent conductive layer 46.

### Other Modifications of First Embodiment

This embodiment may use a semiconductor layer with another configuration in place of the configuration of the semiconductor layer 5 used in the aforementioned solar cells 100, 120 and 140. That is, according to the configuration included in the embodiment, an n-type μc-Si layer, an i-type μc-Si layer and a p-type μc-Si layer are laminated on one another to form an a-Si uni-junction structure in place of the semiconductor layer 5. Further, a multi-junction type (tandem type) configuration described as the semiconductor layer 5 is also included in this embodiment. That is, according to another configuration of the embodiment, an n-i-p junction structure using a μc-Si layer as an i-layer and an n-i-p junction structure using an a-Si layer as an i-layer are laminated on each other through a tunnel junction layer. Further, a triple type is also included in this embodiment. The triple type includes a configuration in which two n-i-p junction structure using μc-Si layers as i-layers and an n-i-p junction structure using an a-Si layer as an i-layer are laminated on each other, a configuration in which an n-i-p junction structure using a μc-Si layer as an i-layer, an n-i-p junction structure using an a-SiGe as an i-layer and an n-i-p junction structure using an a-Si layer as an i-layer are laminated on each other through tunnel junction layers, etc. According to another preferable configuration of the semiconductor layer 5, a uni-junction photoelectric conversion layer using amorphous SiGe may be used, or a multi-junction type photoelectric conversion layer using amorphous SiGe and a-Si may be used. Moreover, non-intrinsic Si alloys such as amorphous SiO, microcrystal SiO, etc. may be used as the constituent materials of n-layers or p-layers in the semiconductor layer 5. Furthermore, various additional technical contrivances may be made so that configuration with the photoelectric conversion efficiency enhanced can be used. For example, intrinsic or non-intrinsic Si alloys such as amorphous SiO, microcrystal SiO, etc., a-Si or μc-Si may be additionally placed as interface layers.

Further, a preferable configuration included in this embodiment may be, for example, implemented with a solar cell module in which an SCAF (Series Connection through Apertures formed on Film) structure is used to achieve a series connection structure without using the collector electrode layer 7 shown in FIG. 1. The SCAF structure is a structure of a solar cell in which a through hole structure penetrating a substrate is built in so that integration based on series connection can be produced in a manufacturing process.

### Second Embodiment

A method for manufacturing a solar cell will be described as a second embodiment of the invention. The manufactured solar cell is the solar cell 120 shown in FIG. 2.

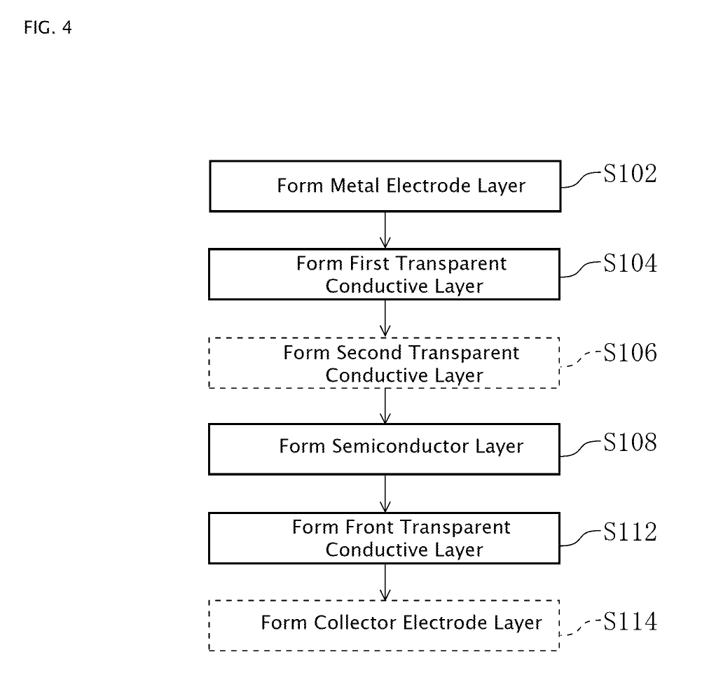

FIG. 4 is a flow chart for explaining the procedure of processing in the method for manufacturing a solar cell. In the method for manufacturing a solar cell according to this embodiment, first, a metal electrode layer 2 is formed on a substrate 1 (S102). In the metal electrode layer 2, on this occasion, a surface (second surface) facing the substrate 1 is formed and a first surface looking upward in FIG. 2 is then formed. The first surface is formed to have an uneven structure. The metal electrode layer 2 has, for example, silver as its primary component, and has light reflectivity. More specifically, the metal electrode layer 2 is formed by a radio-frequency magnetron sputtering method. On this occasion, a silver aluminum alloy (Ag—Al alloy) containing 0.3 atom % (hereinafter referred to as “at %”) aluminum (Al) is used as a sputtering target. As another example of the metal electrode layer 2, Ag, Al or the like may be used.

Argon-oxygen (Ar—O₂) mixed gas is used for film formation as sputtering gas in the sputtering process. That is, first, the substrate 1 is placed at a distance from and in opposition to the aforementioned target disposed in a film formation chamber (not shown) so that one surface of the substrate 1 faces the target. Next, in that state, the Ar—O₂ mixed gas is introduced into the film formation chamber for film formation, and the metal electrode layer 2 is formed on the target-side surface of the substrate 1 by sputtering. As a result, a process for selectively oxidizing only Al while forming the aforementioned metal electrode layer 2 as a film is carried out. Thus, the surface roughness of the film-formed metal electrode layer 2 is increased as compared with the ordinary case where sputtering is performed using only argon (Ar) gas. On this occasion, the metal electrode layer 2 is formed with its set film thickness being set appropriately. Generally when film formation is performed with the other conditions fixed, the increase of the film thickness can increase the surface roughness of the surface, that is, form a sharp uneven structure. The other factors to increase the surface roughness generally include increase of the oxygen partial pressure, increase of the film formation rate, etc. The metal electrode layer 2 is formed with those conditions adjusted suitably to make the uneven structure of the first surface fit to light trapping effect.

The value of the film thickness of the metal electrode layer 2 is preferably not lower than 50 nm and more preferably in a range of from 100 nm to 300 nm.

Next, a first transparent conductive layer 32 is formed on the first surface of the metal electrode layer 2 (S104). As the first transparent conductive layer 32, for example, a film of ZnO is formed by a radio-frequency magnetron sputtering method. During the film formation of the first transparent conductive layer 32, the substrate 1 where the metal electrode layer 2 has been formed is not heated aggressively. When the film formation is performed thus without being heated, the temperature rise of the substrate 1 during the film formation is suppressed. As a result, ZnO which is not crystallized but kept amorphous during the film formation is deposited on the first surface of the metal electrode layer 2. In the sputtering process, it is preferable to use Ar—O₂ mixed gas as sputtering gas. For the reduction of transmittance in the ZnO film formed as the first transparent conductive layer 32 can be prevented by use of such a gas.

The first transparent conductive layer 32 may be deposited preferably to be not thinner than 10 nm and more preferably to have a thickness in a range of from 30 nm to 1 μm.

Successively, a second transparent conductive layer 42 is formed as a transparent conductive layer further laminated on the first transparent conductive layer 32 (S106). As the second transparent conductive layer 42, a film of ZnO may be typically formed by a radio-frequency magnetron sputtering method in the same manner as the first transparent conductive layer 32. It is, however, preferable that the second transparent conductive layer 42 is formed under different conditions from those of the first transparent conductive layer 32. Specifically, it is preferable that the second transparent conductive layer 42 is formed by a film formation process which is carried out while the substrate 1 on which layers up to the first transparent conductive layer 32 have been formed is heated by a heater (not shown) for heating the substrate. The temperature of the substrate is, for example, set at 200° C. In addition, when Ar gas is used as sputtering gas during the process, the resistance of the formed film can be prevented from increasing excessively. The second transparent conductive layer 42 formed thus is, for example, formed into a film which is crystalline in itself. As described above, it is also preferable that the second transparent conductive layer 42 is formed into an amorphous film. Further, the film thickness of the second transparent conductive layer 42 is set at a value preferably not lower than 10 nm and more preferably in a range of from 30 nm to 1 μm.

The aforementioned methods for forming the metal electrode layer 2, the first transparent conductive layer 32 and the second transparent conductive layer 42 are not limited to special sputtering methods. A vacuum deposition method, a mist CVD method, a spray deposition method, a printing method, a coating method, a plating method, etc. may be used suitably as the methods for forming those layers.

After that, a semiconductor layer 5 is formed on the second transparent conductive layer 42 (S108). Here, a structure in which an n-type μc-Si layer, an i-type μc-Si layer and a p-type μc-Si layer are laminated sequentially from the second transparent conductive layer 42 may be used to form a μc-Si uni-junction photoelectric conversion layer in the semiconductor layer 5. Of those layers, the n-layer is first formed using mixed gas including mono-silane (SiH₄) gas, hydrogen (H₂) gas and phosphine (PH₃) gas. Next, the i-layer is formed using mixed gas including SiH₄ gas and H₂ gas. Further, the p-layer is formed using mixed gas including SiH₄ gas, H₂ gas and diborane (B₂H₆) gas. A radio-frequency plasma CVD apparatus is used for forming a semiconductor layer consisting of such a layer configuration. In the plasma CVD apparatus, a parallel plate type shower head electrode is, for example, used as a discharge electrode for formation of the semiconductor layer 5 which will operate as a photoelectric conversion layer.

On this occasion, it is preferable that each layer of the n-, i- and p-layers has a film thickness suitable for generating electric power efficiently due to light trapping effect in the solar cell 120. More specifically, the layers are, for example, sequentially set at 45 nm, 2 μm and 30 nm respectively.

The film formation may be performed in the state where the substrate conveyed stepwise is standing still or in the state where the substrate is being conveyed continuously. Even when a semiconductor layer having another configuration as described in the first embodiment is used, the semiconductor layer having the intended layer configuration can be produced. On that occasion, the semiconductor layer can be formed if film formation conditions such as source gas are combined suitably in accordance with the formation order of films or layers.

Further, a front transparent conductive layer 6 is formed on the semiconductor layer 5 formed thus (S110). In this embodiment, a film of ITO is formed as the front transparent conductive layer 6 by a sputtering method. Other transparent conductive oxides such as IZO, TiO₂, ZnO, SnO₂, In₂O₃, Ga₂O₃, IGO, IGZO, etc. may be used as the constituent material of the front transparent conductive layer 6. Further, the film formation method for forming the front transparent conductive layer 6 is not limited to the sputtering method. For example, a vacuum deposition method, a mist CVD method, a spray deposition method, a printing method, a coating method, a plating method, etc. may be used as the film formation method.

Finally, a film of a Ti/Ag electrode is formed as a collector electrode layer 7 by an electron beam deposition method using a metal mask (S112). The film formation method for forming the collector electrode layer 7 is not limited to the electron beam deposition method. Methods such as a sputtering method, a vacuum deposition method, a spray deposition method, a printing method, a plating method, etc. may be used in this embodiment.

### EXAMPLE AND COMPARATIVE EXAMPLE

A sample as Example of the aforementioned solar cell according to the first and second embodiments and a sample as Comparative Example of a solar cell to be compared with the sample of Example were produced. Specifically, the solar cell 120 (FIG. 2) was produced as a sample of Example according to the method for manufacturing a solar cell described as the second embodiment. In this sample of Example, a SCHOTT D-263 glass substrate was used as the substrate 1. The metal electrode layer 2 was made from a silver aluminum alloy (Ag—Al alloy) containing 0.3 at % aluminum (Al) and formed to be 200 nm thick by a radio-frequency magnetron sputtering method.

In addition, a film of ZnO was formed as the first transparent conductive layer 32 by a radio-frequency magnetron sputtering method. The first transparent conductive layer 32 was formed to reach a set film thickness of 450 nm. The film of the first transparent conductive layer 32 was formed without aggressive heating, so that the temperature rise of the substrate was suppressed. As a result, ZnO formed as the material of the first transparent conductive layer 32 was not crystallized but made amorphous. Then, a film of ZnO was formed as the second transparent conductive layer 42 with a set film thickness of 50 nm by a radio-frequency magnetron sputtering method. On this occasion, the film formation process was carried out while the substrate was heated by a heater for heating the substrate to make the substrate temperature reach 200° C.

The semiconductor layer 5 had a uni-junction structure using μc-Si as an i-layer. The semiconductor layer 5 was formed so that the film thicknesses of an n-layer, an i-layer and a p-layer reached 45 nm, 2 μm and 30 nm respectively. Then, a film of ITO was formed to be 70 nm thick as the front transparent conductive layer 6. Finally, a Ti/Ag electrode was formed as the collector electrode layer 7 by an electron beam deposition method using a metal mask. On this occasion, the film thicknesses of Ti and Ag layers were set at 100 nm and 500 nm respectively. In the sample of Example produced as described above, the second transparent conductive layer 42 using amorphous ZnO as a transparent conductive material was formed.

On the other hand, in the sample of Comparative Example, a single transparent conductive layer was formed in place of the first transparent conductive layer 32 and the second transparent conductive layer 42 in the configuration of the sample of Example and in the same position and with the same thickness as those layers. As for the film formation conditions in this case, a film of ZnO was formed under sputtering conditions different from the conditions for the first transparent conductive layer 32, so as to obtain a crystalline ZnO transparent conductive layer. Specifically, the transparent conductive layer in the sample of Comparative Example was formed with a set film thickness of 500 nm while the substrate temperature was set at 350° C. by a heater. Thus, the sample of Comparative Example which had a crystalline ZnO transparent conductive layer in place of the first transparent conductive layer 32 and the second transparent conductive layer 42 in the configuration of the sample of Example was produced.

Effects in the first and second embodiments of the invention were confirmed in production of each sample as follows. That is, surface roughness was measured on the surface of the uppermost layer in each of two stages on the way of production of each of the sample of Example and the sample of Comparative Example. Specifically, in the sample of Example, surface roughness was measured in two surfaces, one of which was the upper surface (first surface) of the metal electrode layer 2 and the other of which was the upper surface of the second transparent conductive layer 42 which was located as the uppermost layer in the stage just before the semiconductor layer 5 was formed. On the other hand, in the sample of Comparative Example, surface roughness was measured in two surfaces, one of which was the upper surface (first surface) of the metal electrode layer 2 in the same manner as in the sample of Example and the other of which was the upper surface of the crystalline transparent conductive layer. Those surfaces were measured using an atomic force microscope (AFM). Table 1 shows results of surface roughness measured as described above.

TABLE 1

| | Measurement location | Ra |
|---|---|---|
| Example | Upper surface of second transparent | about |
| | conductive layer 42 | 15 nm |
| | Upper surface (first surface) of metal | about |
| | electrode layer 2 | 35 nm |
| Comparative | Upper surface of crystalline transparent | about |
| Example | conductive layer | 30 nm |
| | Upper surface (first surface) of metal | about |
| | electrode layer 2 | 35 nm |

As described above, in the sample of Comparative Example, the surface roughness Ra of the uneven structure in the upper surface of the metal electrode layer 2 was about 35 nm, while the surface roughness Ra was slightly reduced to about 30 nm due to the crystalline transparent conductive layer. That is, the crystalline transparent conductive layer in the sample of Comparative Example exerted a slight flattening or smoothing effect. On the other hand, in the sample of Example, the surface roughness Ra of the uneven structure in the upper surface of the metal electrode layer 2 was about 35 nm, which was as large as in the sample of Comparative Example, while the surface roughness Ra in the upper surface of the second transparent conductive layer 42 was about 15 nm. That is, a great flattening or smoothing effect was exerted by the transparent conductive layer configuration used in the sample of Example, where the first transparent conductive layer 32 which was thick and amorphous and the second transparent conductive layer 42 which was thin and crystalline were combined. Incidentally, the uneven structure was produced in the first surface of the metal electrode layer 2 so as to be desired in view from light trapping effect. To this end, the value of the surface roughness Ra in the first surface of the desired metal electrode layer should reach about 30 nm or higher according to the investigation of the inventor of the application. In each of the sample of Example and the sample of Comparative Example, the surface roughness Ra in the first surface of the metal electrode layer 2 was measured to be about 35 nm, showing that each configuration could exert a satisfactory light trapping effect.

Further, the characteristics of μc-Si solar cells based on the sample of Comparative Example and the sample of Example were measured by a solar simulator, and the measured results were evaluated. As a result, the fill factor in the measured result obtained from the sample of Comparative Example was 0.65. On the other hand, the fill factor in the measured result obtained from the sample of Example was improved to 0.70. Due to the improvement of the fill factor, the photoelectric conversion efficiency as a solar cell can be improved.

As described above, even when the uneven structure formed in the semiconductor layer 5 side surface (first surface) of the metal electrode layer 2 had a large surface roughness, the underlying surface on which the semiconductor layer 5 should be formed, that is, the interface was flattened or smoothed greatly so that the surface roughness thereof was reduced. This is because an amorphous transparent conductive material was used for the first transparent conductive layer 32. In addition, in comparison with the sample of Comparative Example, the photoelectric conversion characteristic of the semiconductor layer 5 in the sample of Example was excellent in accordance with the degree with which the underlying surface was flattened. The inventor of the application infers that such improvement of the solar cell characteristic is caused by the flattened underlying surface leading to the improvement of the film quality of the semiconductor layer 5 formed thereon. That is, the inventor of the application infers that the surface roughness in the upper surface of the metal electrode layer 2 is common to the two samples so that there should be no difference in degree of light diffusion/reflection, that is, in light trapping effect between the two samples.

### Other Embodiments

Besides various methods, conditions, apparatuses and materials shown specifically in the aforementioned embodiments, various methods may be used to carry out the invention. Such other embodiments relating to a semiconductor layer and a transparent conductive layer will be described below.

Various apparatuses may be used as the plasma CVD apparatus for forming a semiconductor layer as shown in the first and second embodiments. For example, a discharge electrode with another configuration than the configuration of the parallel plate type shower head electrode may be used as the discharge electrode of the plasma CVD apparatus. In addition, for example, in a configuration using a belt-like or long substrate, it is possible to use a plasma CVD apparatus which performs film formation in the state where the substrate conveyed stepwise is standing still or in the state where the substrate is being conveyed continuously.

In addition, embodiments of the invention may be applied to a uni-function type thin-film solar cell in which a-Si or amorphous SiGe is used as the constituent material of the i-layer in the semiconductor layer 5 shown in the first and second embodiments, or a multi-junction type thin-film solar cell in which any one of a-Si, amorphous SiGe, μc-Si, etc. is used likewise. In addition, non-intrinsic Si alloys such as amorphous SiO, microcrystal SiO, etc. may be used as the constituent materials of the n- and p-layers in the semiconductor layer 5. Further, intrinsic or non-intrinsic Si alloys such as amorphous SiO, microcrystal SiO, etc., a-Si or μc-Si may be additionally placed as an interface layer.

Some embodiments of the invention have been described above specifically. The aforementioned embodiments were described for explaining the invention, and the scope of the invention herein is to be set up based on the scope of claims thereof. In addition, modifications which should be present within the scope of the invention, including other combinations of the embodiments, are to be included in the scope of the invention.

According to aspects of the invention, for example, a thin-film solar cell using μc-Si or a-Si as a power generation layer can be implemented as a solar cell whose photoelectric conversion efficiency is rarely lowered even when a substantially intrinsic Si layer is formed to be thin. Thus, embodiments of the invention makes a great contribution to manufacturing an excellent-performance solar cell in a short tact time.

This application is based on, and claims priority to, Japanese Patent Application No. 2010-059204, filed on Mar. 16, 2010. The disclosure of the priority application, in its entirety, including the drawings, claims, and the specification thereof, is incorporated herein by reference.

What is claimed is:

1. A thin-film solar cell comprising:
a metal electrode layer which has a first surface and a second surface, the first surface including an uneven structure with light reflectivity, the metal electrode layer being disposed on one surface of a substrate so as to allow the second surface to face the one surface of the substrate;
a first transparent conductive layer which contains an amorphous transparent conductive material;
a semiconductor layer; and
a front transparent conductive layer; wherein:
the first transparent conductive layer, the semiconductor layer and the front transparent conductive layer are disposed on the first surface of the metal electrode layer sequentially from the substrate.

2. A thin-film solar cell according to claim 1, further comprising:
a second transparent conductive layer which is disposed between the first transparent conductive layer and the semiconductor layer and which contains a crystalline transparent conductive material.

3. A thin-film solar cell according to claim 2, wherein:
the first transparent conductive layer is made from an amorphous transparent conductive material containing one transparent conductive material selected from a group including In₂O₃—ZnO, In₂O₃—Ga₂O₃—ZnO and In₂O₃—Ga₂O₃; and
the second transparent conductive layer is made from a transparent conductive material free from indium.

4. A thin-film solar cell according to claim 2, wherein:
the first transparent conductive layer is made from an amorphous transparent conductive material containing one transparent conductive material selected from a group including ZnO, SnO₂, GaO₂, TiO₂, ITO and In₂O₃; and
the second transparent conductive layer is made from a transparent conductive material free from indium.

5. A thin-film solar cell according to claim 4, wherein:
the second transparent conductive layer contains a material or a component which can inject carriers into the first transparent conductive layer or the semiconductor layer.

6. A thin-film solar cell according to claim 3, wherein:
the second transparent conductive layer is made from a transparent conductive material which prevents indium from being diffused from the first transparent conductive layer to the semiconductor layer.

7. A thin-film solar cell according to claim 2, wherein:
the second transparent conductive layer is thinner than the first transparent conductive layer.

8. A thin-film solar cell according to claim 1, further comprising:
a third transparent conductive layer which is disposed between the first transparent conductive layer and the semiconductor layer and which contains an amorphous transparent conductive material different from the material of the first transparent conductive layer.

9. A thin-film solar cell according to claim 1, wherein:
surface roughness of an interface between a film or a layer contacting the semiconductor layer on the substrate side and the semiconductor layer is lower than surface roughness of the first surface.

10. A thin-film solar cell according to claim 9, wherein:
surface roughness Ra of the interface is not higher than 15 nm.

11. A thin-film solar cell according to claim 1, wherein:
surface roughness Ra of the first surface is not lower than 30 nm.

12. A method for manufacturing a thin-film solar cell, comprising the steps of:
placing a metal electrode layer on one surface of a substrate, the metal electrode layer including a first surface and a second surface, an uneven structure with light reflectivity being provided on the first surface, the second surface facing the one surface of the substrate;
placing a first transparent conductive layer containing an amorphous transparent conductive material;
placing a semiconductor layer; and
placing a front transparent conductive layer; wherein:
the step of placing the first transparent conductive layer, the step of placing the semiconductor layer and the step of placing the front transparent conductive layer are executed sequentially in this order after the step of placing the metal electrode layer.

13. A method for manufacturing a thin-film solar cell according to claim 12, further comprising the step of:
placing a second transparent conductive layer containing a crystalline transparent conductive material; wherein:
the step of placing the second transparent conductive layer is executed between the step of placing the first transparent conductive layer and the step of placing the semiconductor layer.

14. A method for manufacturing a thin-film solar cell according to claim 13, wherein:
the step of placing the first transparent conductive layer is a step of forming the first transparent conductive layer out of an amorphous transparent conductive material containing one transparent conductive material selected from a group including In₂O₃—ZnO, In₂O₃—Ga₂O₃—ZnO and In₂O₃—Ga₂O₃; and
the step of placing the second transparent conductive layer is a step of forming the second transparent conductive layer out of a transparent conductive material free from indium.

15. A method for manufacturing a thin-film solar cell according to claim 13, wherein:
the step of placing the first transparent conductive layer is a step of forming the first transparent conductive layer out of an amorphous transparent conductive material containing one transparent conductive material selected from a group including ZnO, SnO₂, GaO₂, TiO₂, ITO and In₂O₃; and
the step of placing the second transparent conductive layer is a step of disposing the second transparent conductive layer out of a transparent conductive material free from indium.

16. A method for manufacturing a thin-film solar cell according to claim 14, wherein:
the second transparent conductive layer contains a material or a component which can inject carriers into the first transparent conductive layer or the semiconductor layer.

17. A method for manufacturing a thin-film solar cell according to claim 14, wherein:
the second transparent conductive layer is made from a transparent conductive material which prevents indium from being diffused from the first transparent conductive layer to the semiconductor layer.

18. A method for manufacturing a thin-film solar cell according to claim 12, further comprising the step of:
placing a third transparent conductive layer containing an amorphous transparent conductive material different from the material of the first transparent conductive layer; wherein:
the step of placing the third transparent conductive layer is executed between the step of placing the first transparent conductive layer and the step of placing the semiconductor layer.

19. A method for manufacturing a thin-film solar cell according to claim 12, wherein:
surface roughness of an interface between a film or a layer contacting the semiconductor layer on the substrate side and the semiconductor layer is made lower than surface roughness of the first surface.

20. A method for manufacturing a thin-film solar cell according to claim 12, wherein:
in the step of placing the metal electrode layer, a silver alloy containing aluminum is sputtered with sputtering gas containing oxygen.
